(19) United States
(12) Patent Application Publication
(10) Pub. No.: US 2021/0202585 A1
(43) Pub. Date: Jul. 1, 2021

(54) Display Panel And Display Device

(71) Applicant: Shanghai Tianma Micro-Electronics Co., Ltd., Shanghai (CN)

(72) Inventor: Haijing CHEN, Shanghai (CN)

(73) Assignee: Shanghai Tianma Micro-Electronics Co., Ltd., Shanghai (CN)

(21) Appl. No.: 16/877,995

(22) Filed: May 19, 2020

(30) Foreign Application Priority Data
Dec. 26, 2019 (CN) 201911369338.3

(51) Int. Cl. H01L 27/32; H01L 51/52

(52) U.S. Cl. CPC H01L 27/322; H01L 51/5218; H01L 27/3276

(57) ABSTRACT

Provided are a display panel and a display device. The display panel includes a display region, the display region includes a plurality of pixels, and each pixel includes a plurality of pixel regions, wherein the plurality of pixel regions includes a first color region and a second color region and an emission wavelength of the first color region is greater than an emission wavelength of the second color region. The display panel further includes a substrate and a plurality of reflective components, including a first reflective component and a second reflective component, wherein at least a portion of the first reflective component is disposed in the first color region and the second reflective component is disposed in the second color region. The display panel further includes a plurality of color filter components disposed on a side of the plurality of reflective components facing away from the substrate.

### CROSS-REFERENCE TO RELATED APPLICATION

This application claims priority to Chinese Patent Application No. CN201911369338.3, filed on Dec. 26, 2019 and titled “DISPLAY PANEL AND DISPLAY DEVICE”, the disclosure of which is incorporated herein by reference in its entirety.

### TECHNICAL FIELD

The present disclosure relates to the field of display technologies and, in particular, to a display panel and a display device.

### BACKGROUND

An organic light emitting diode (OLED) display is a type of self-emitting display. Compared with a liquid crystal display (LCD), the OLED display does not need a backlight, and is therefore thinner and more lightweight. In addition, the OLED display is increasingly used in various high-performance display fields due to its various advantages, including high brightness, low power consumption, a wide viewing angle, a high response speed, a wide operating temperature range, and the like.

In the related art, a commonly used OLED display is generally provided with a red pixel unit, a green pixel unit, and a blue pixel unit, and a color filter substrate with three primary colors of red, green, and blue in structure. Although an OLED display device with this structure has higher color purity and a wider color gamut, when the OLED display device is in a dark state, a screen of the OLED display device exhibits a significant color separation phenomenon from a lateral view.

### SUMMARY

The present disclosure provides a display panel and a display device that solves the problem of color separation from a lateral view.

In a first aspect, an embodiment of the present disclosure provides a display panel. The display panel includes a display region, a substrate, a plurality of reflective components, and a plurality of color filter components. The display region includes a plurality of pixels, each of the plurality of pixels includes a plurality of pixel regions, and each of the plurality of pixel regions includes a first color region and a second color region, wherein an emission wavelength of the first color region is greater than an emission wavelength of the second color region.

The plurality of reflective components is disposed on a side of the substrate, wherein the plurality of reflective components includes a first reflective component and a second reflective component, at least a portion of the first reflective component is disposed in the first color region, and the second reflective component is disposed in the second color region.

The plurality of color filter components is disposed on a side of the plurality of reflective components facing away from the substrate, wherein the plurality of color filter components includes a first color filter component and a second color filter component, at least a portion of the first color filter component is disposed in the first color region and the first color filter component is transmissive for light of a first color, and the second color filter component is disposed in the second color region and is transmissive for light of a second color.

In a direction perpendicular to the substrate, in each pixel among the plurality of pixels, an overlapping area of the first color filter component and the first reflective component is equal to an overlapping area of the second color filter component and the second reflective component.

In a second aspect, an embodiment of the present disclosure provides a display device incorporating the display panel described in the first aspect.

### BRIEF DESCRIPTION OF DRAWINGS

FIG. 1 is a top view of a display panel according to an embodiment of the present disclosure;

FIG. 2 is an enlarged view of region P1 in FIG. 1;

FIG. 3 is a sectional view of FIG. 2 along a line AN;

FIG. 4 is a top view of another display panel according to an embodiment of the present disclosure;

FIG. 5 is a top view of another display panel according to an embodiment of the present disclosure;

FIG. 6 is a sectional view of FIG. 5 along a line BB′;

FIG. 7 is a top view of another display panel according to an embodiment of the present disclosure;

FIG. 8 is a sectional view of FIG. 7 along a line CC′;

FIG. 9 is a sectional view of another display panel according to an embodiment of the present disclosure;

FIG. 10 is a sectional view of another display panel according to an embodiment of the present disclosure;

FIG. 11 is a top view of another display panel according to an embodiment of the present disclosure;

FIG. 12 is a sectional view of FIG. 11 along a line DD′;

FIG. 13 is a top view of another display panel according to an embodiment of the present disclosure;

FIG. 14 is a sectional view of FIG. 13 along a line EE′;

FIG. 15 is a top view of another display panel according to an embodiment of the present disclosure;

FIG. 16 is a top view of another display panel according to an embodiment of the present disclosure;

FIG. 17 is a top view of another display panel according to an embodiment of the present disclosure;

FIG. 18 is a sectional view of FIG. 17 along a line FF′;

FIG. 19 is a top view of another display panel according to an embodiment of the present disclosure;

FIG. 20 is a sectional view of FIG. 19 along a line GG′; and

FIG. 21 is a structural view of a display device according to an embodiment of the present disclosure.

### DETAILED DESCRIPTION

Hereinafter a display panel and display device will be further described in detail in conjunction with the embodiments shown in the accompanying drawings. It is to be understood that the specific embodiments set forth herein are merely intended to illustrate and not to limit the present disclosure. Additionally, it is to be noted that for ease of description, merely part, not all, of the structures related to the present disclosure are illustrated in the drawings.

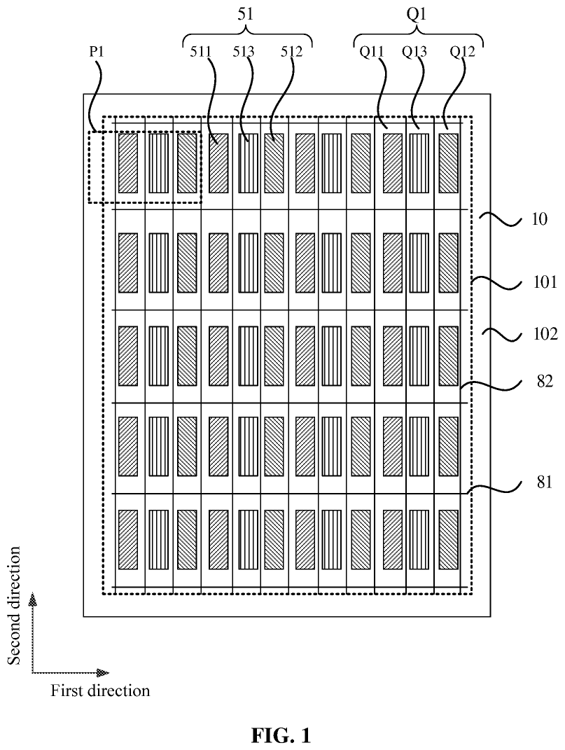

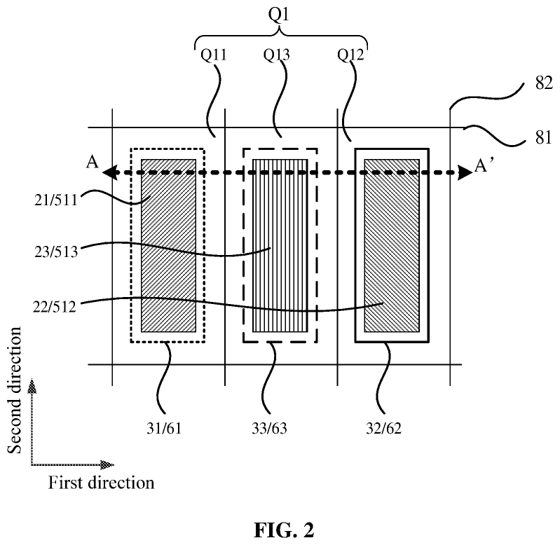

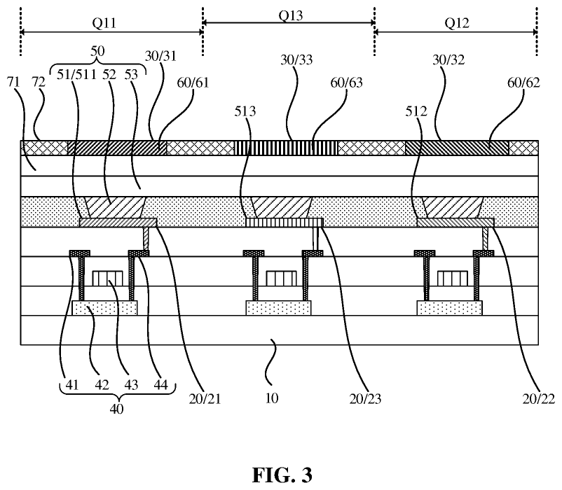

FIG. 1 is a top view of a display panel according to an embodiment of the present disclosure. FIG. 2 is an enlarged view of region P1 in FIG. 1. FIG. 3 is a sectional view of FIG. 2 along a line AA′. Referring to FIG. 1, FIG. 2 and FIG. 3, a display panel includes a display region 101, wherein the display region 101 includes a plurality of pixels, each of the plurality of pixels includes a plurality of pixel regions Q1 (exemplarily, in FIG. 1 and FIG. 2, one pixel includes three pixel regions Q1), the plurality of pixel regions Q1 includes a first color region Q11 and a second color region Q12, wherein an emission wavelength of the first color region Q11 is greater than an emission wavelength of the second color region Q12. The display panel includes a substrate 10, a plurality of reflective components 20, and a plurality of color filter components 30. The plurality of reflective components 20 is disposed on a side of the substrate 10 and includes a first reflective component 21 and a second reflective component 22, where at least a portion of the first reflective component 21 is disposed in the first color region Q11, and the second reflective component 22 is disposed in the second color region Q12. The plurality of color filter components 30 is disposed on a side of the plurality of reflective components 20 facing away from the substrate 10, wherein the plurality of color filter components 30 includes a first color filter component 31 and a second color filter component 32, at least a portion of the first color filter component 31 is disposed in the first color region Q11 and the first color filter component 31 is transmissive for light of a first color, and the second color filter component 32 is disposed in the second color region Q12 and transmissive for light of a second color. In a direction perpendicular to the substrate 10, in a same pixel among the plurality of pixels (one pixel is shown in FIG. 2), an overlapping area of the first color filter component 31 and the first reflective component 21 is equal to an overlapping area of the second color filter component 32 and the second reflective component 22.

In the display panel provided by the present embodiment of the disclosure, in the direction perpendicular to the substrate 10, the first reflective component 21 overlaps with the first color filter component 31. Light in an ambient environment passes through the first color filter component 31, is reflected off the first reflective component 21, and passes through the first color filter component 31 again. Therefore, light that passes through the first color filter component 31 can be reflected by the first reflective component 21 and be seen by human eyes, such that a vertical overlapping area of the first color filter component 31 and the first reflective component 21 constitutes an effective reflective area. Similarly, in the direction perpendicular to the substrate 10, the second reflective component 22 overlaps with the second color filter component 32. Light in the ambient environment passes through the second color filter component 32, is reflected off the second reflective component 22, and passes through the second color filter component 32 again. Therefore, a vertical overlapping area of the second color filter component 32 and the second reflective component 22 constitutes an effective reflective area. In the embodiment of the present disclosure, in the same pixel (one pixel is shown in FIG. 2), the vertical overlapping area of the first color filter component 31 and the first reflective component 21 is equal to the vertical overlapping area of the second color filter component 32 and the second reflective component 22, such that the effective reflective area corresponding to the first color filter component 31 is equal to the effective reflective area corresponding to the second color filter component 32, and the light of the first color reflected through the first color filter component 31 and the light of the second color reflected through the second color filter component 32 have a similar light intensity or even the same light intensity, thereby solving the problem of color separation from a lateral view.

Optionally, referring to FIG. 1, FIG. 2, and FIG. 3, each of the plurality of reflective components 20 includes a reflective electrode 51, where the reflective electrode 51 refers to an electrode having a function of reflecting light. Each of the plurality of color filter components 30 includes a color filter 60. In the direction perpendicular to the substrate 10, the color filter 60 completely covers the reflective electrode 51 in a same pixel region Q1 among the plurality of pixel regions Q1. A plurality of reflective electrodes 51 includes a first reflective electrode 511 disposed in the first color region Q11 and a second reflective electrode 512 disposed in the second color region Q12, wherein in the direction perpendicular to the substrate 10, an area of the first reflective electrode 511 is equal to an area of the second reflective electrode 512. In the present embodiment of the disclosure, the reflective electrode 51 serves as the reflective component 20, the color filter 60 serves as the color filter component 30, and the color filter 60 completely cover the reflective electrode 51 in the same pixel region Q1. Therefore, as long as an area of a vertical projection (i.e. in the direction perpendicular to the substrate 10) of the first reflective electrode 511 on the substrate 10 is equal to the area of the second reflective electrode 512, it can be ensured that, in the same pixel (one pixel is shown in FIG. 2), the vertical overlapping area of the first color filter component 31 and the first reflective component 21 is equal to the vertical overlapping area of the second color filter component 32 and the second reflective component 22, thereby simplifying a design process.

Optionally, referring to FIG. 1, FIG. 2, and FIG. 3, the plurality of pixel regions Q1 is arranged in a matrix along a first direction and a second direction. Along the first direction, a width of the first reflective electrode 511 is equal to a width of the second reflective electrode 512. Along the second direction, a length of the first reflective electrode 511 is equal to a length of the second reflective electrode 512. Since the plurality of pixel regions Q1 is arranged in the matrix along the first direction and the second direction, in the present embodiment of the disclosure, the first reflective electrode 511 and the second reflective electrode 512 are also arranged in the matrix along the first direction and the second direction, and the first reflective electrode 511 and the second reflective electrode 512 have a same length along the first direction and the second direction, thereby simplifying a manufacturing process. In other implementation modes, the first reflective electrode 511 and the second reflective electrode 512 may be arranged in other modes.

Exemplarily, referring to FIG. 1, FIG. 2, and FIG. 3, the display panel may further include a non-display region 102, where the non-display region 102 surrounds the display region 101. A plurality of scanning lines 81 and a plurality of data lines 82 may be provided in the display region 101. The plurality of scanning lines 81 extends along the first direction and repeats linearly along the second direction, the plurality of data lines 82 extends along the second direction and repeats linearly along the first direction, and the plurality of scanning lines 81 and the plurality of data lines 82 intersect with each other to form the plurality of pixel regions Q1. The display panel may further include light emitting units 50 and pixel drive circuits, where the pixel drive circuits are disposed between the light emitting units 50 and the substrate 10. Each of the light emitting units 50 may include the reflective electrode 51, a light emitting function layer 52, and an opposite electrode 53. Each of the pixel drive circuits may include a thin film transistor 40, wherein the thin film transistor 40 includes a source 41, a semiconductor layer 42, a gate 43, and a drain 44. The drain 44 of the thin film transistor 40 is electrically connected to the reflective electrode 51 of the light emitting unit 50. The display panel may further include a thin film encapsulation layer 71 and a black matrix 72, where the thin film encapsulation layer 71 is disposed between a film containing the plurality of color filters 60 and a film containing a plurality of light emitting units 50. The black matrix 72 is disposed between two adjacent color filters 60. The color filter 60 may be formed in an opening of the latticed black matrix 72.

Optionally, referring to FIG. 1, FIG. 2, and FIG. 3, the first color region Q11 emits red light or green light, and the second color region Q12 emits blue light.

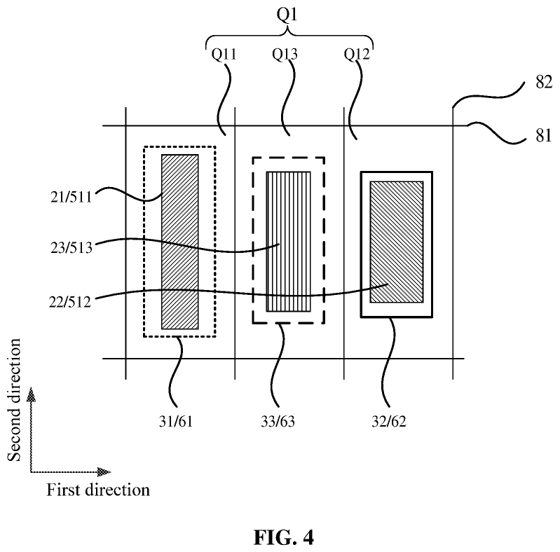

FIG. 4 is a top view of a display panel according to another embodiment of the present disclosure. Referring to FIG. 4, one pixel is shown in FIG. 4, and the plurality of pixel regions Q1 is arranged in the matrix along the first direction and the second direction. Along the first direction, the width of the first reflective electrode 511 is less than the width of the second reflective electrode 512. Along the second direction, the length of the first reflective electrode 511 is greater than the length of the second reflective electrode 512.

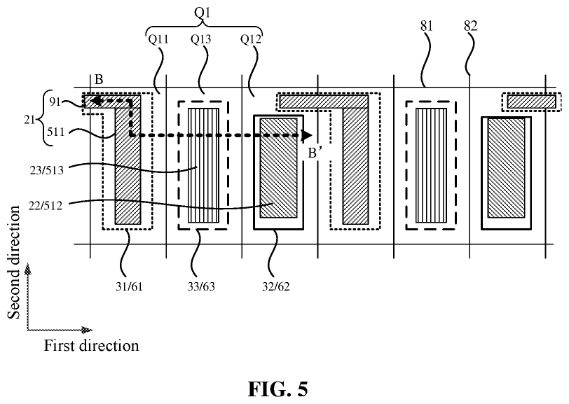

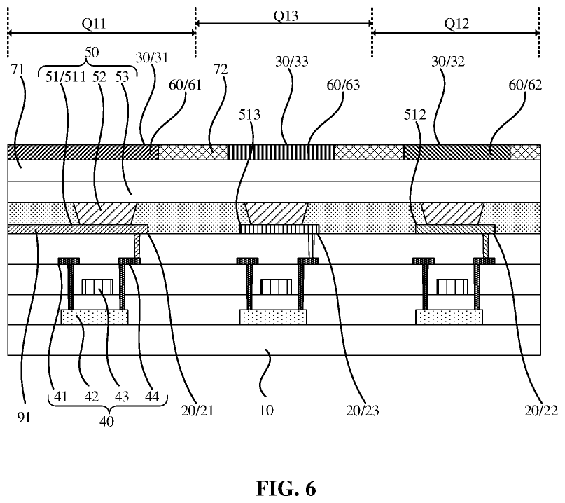

FIG. 5 is a top view of a display panel according to another embodiment of the present disclosure. FIG. 6 is a sectional view of FIG. 5 along a line BB′. Referring to FIG. 5 and FIG. 6, each reflective component 20 includes the reflective electrode 51, and each color filter component 30 includes the color filter 60. In the direction perpendicular to the substrate 10, the color filter 60 completely covers the reflective electrode 51 in the same pixel region Q1. The first reflective component 21 includes the first reflective electrode 511 and a first reflection assistance element 91, where the first reflective electrode 511 is disposed in the first color region Q11. The second reflective component 22 includes the second reflective electrode 512, where the second reflective electrode 512 is disposed in the second color region Q12. In the direction perpendicular to the substrate 10, the first color filter component 31 covers at least a portion of the first reflection assistance element 91. In the direction perpendicular to the substrate 10, in the same pixel (two pixels are shown in FIG. 5), an overlapping area of the first color filter component 31 and the first reflection assistance element 91 constitutes a first area, and a sum of the first area and an area of the first reflective electrode 511 is equal to a total area of the second reflective electrode 512. In the present embodiment of the disclosure, the first reflective electrode 511 and the first reflection assistance element 91 together constitute the first reflective component 21 such that a design of the first reflective component 21 is not limited to the first reflective electrode 511.

Optionally, referring to FIG. 5 and FIG. 6, the first reflection assistance element 91 and the first reflective electrode 511 are disposed in a same layer and made of a same material, the first reflection assistance element 91 is electrically connected to the first reflective electrode 511, and, in the direction perpendicular to the substrate 10, the first reflection assistance element 91 does not overlap with the second reflective electrode 512. In the present embodiment of the disclosure, the first reflection assistance element 91 and the first reflective electrode 511 are disposed in the same layer and made of the same material, such that the first reflection assistance element 91 and the first reflective electrode 511 can be formed in a same process, thereby simplifying a manufacturing process. In another aspect, the emission wavelength of the first color region Q11 is greater than the emission wavelength of the second color region Q12, and a turn-on voltage of the light emitting unit 50 in the first color region Q11 is less than a turn-on voltage of the light emitting unit 50 in the second color region Q12. The first reflection assistance element 91 is electrically connected to the first reflective electrode 511, and effectively acts as a voltage-dividing resistor for the turn-on voltages in series to the first reflective electrode 511. This arrangement prevents the light emitting unit 50 in the first color region Q11 from displaying an inaccurate gray scale.

Exemplarily, referring to FIG. 5 and FIG. 6, the first color region Q11 emits the red light or the green light, and the second color region Q12 emits the blue light. The turn-on voltage of the light emitting unit 50 in the second color region Q12 is greater than the turn-on voltage of the light emitting unit 50 in the first color region Q11.

Exemplarily, referring to FIG. 5 and FIG. 6, the first reflective component 21 includes the first reflective electrode 511 and the first reflection assistance element 91, and the first color filter component 31 includes a first color filter 61. In the direction perpendicular to the substrate 10, the first color filter 61 covers the first reflective electrode 511 and the first reflection assistance element 91. The first reflection assistance element 91 is disposed in the first color region Q11 and the second color region Q12. The second reflective component 22 includes the second reflective electrode 512, and the second color filter component 32 includes a second color filter 62. In the direction perpendicular to the substrate 10, the second color filter 62 covers the second reflective electrode 512.

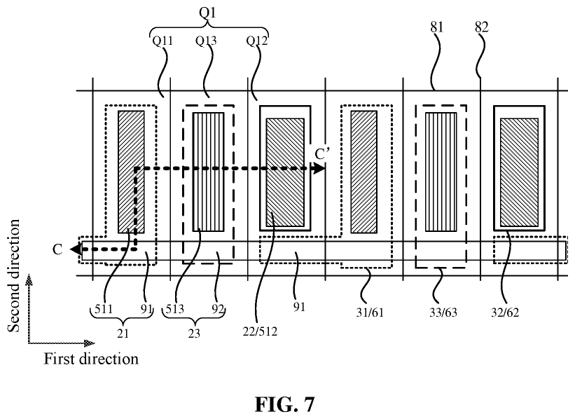

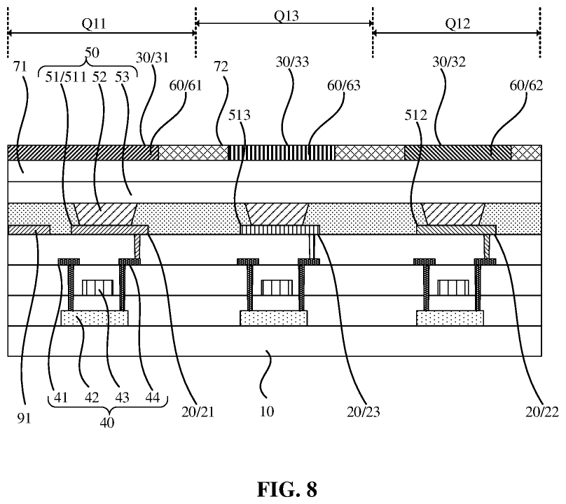

FIG. 7 is a top view of a display panel according to another embodiment of the present disclosure. FIG. 8 is a sectional view of FIG. 7 along a line CC′. Referring to FIG. 7 and FIG. 8, two pixels are shown in FIG. 7, the first reflective component 21 includes the first reflective electrode 511 and the first reflection assistance element 91, and the first reflection assistance element 91 is electrically insulated from any one of the plurality of reflective electrodes 51. The first reflection assistance element 91 is electrically insulated from the first reflective electrode 511 and the second reflective electrode 512.

Optionally, referring to FIG. 7 and FIG. 8, the first reflection assistance element 91 and the first reflective electrode 511 are disposed in the same layer and made of the same material. In the present embodiment of the disclosure, the first reflection assistance element 91 and the first reflective electrode 511 are disposed in the same layer and made of the same material, such that the first reflection assistance element 91 and the first reflective electrode 511 can be formed in the same process, thereby simplifying a manufacturing process.

Exemplarily, referring to FIG. 7 and FIG. 8, the first reflection assistance element 91 and the first reflective electrode 511 are disposed in the same layer. In the direction perpendicular to the substrate 10, the first reflection assistance element 91 does not overlap with any one of the plurality of reflective electrodes 51.

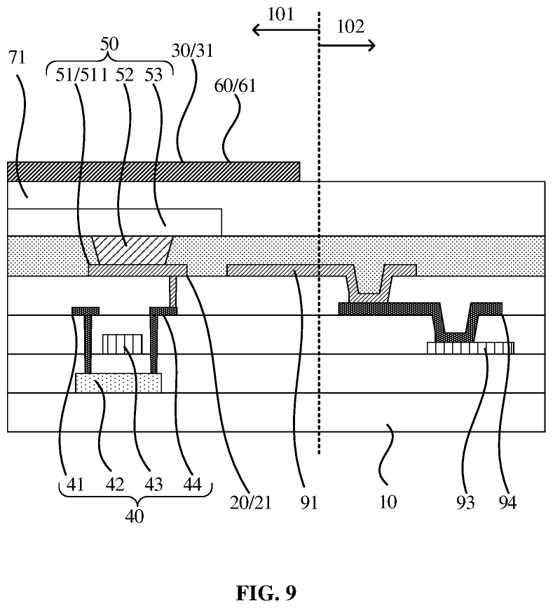

FIG. 9 is a sectional view of a display panel according to another embodiment of the present disclosure. Referring to FIG. 7, FIG. 8, and FIG. 9, the first reflection assistance element 91 is electrically insulated from any one of the plurality of reflective electrodes 51, and the first reflection assistance element 91 and the first reflective electrode 511 are disposed in the same layer. The display panel further includes a reference voltage supply signal line 93, wherein the first reflection assistance element 91 is electrically connected to the reference voltage supply signal line 93. Since the reference voltage supply signal line 93 has a stable potential, the first reflection assistance element 91 is electrically connected to the reference voltage supply signal line 93. This arrangement prevents the first reflection assistance element 91 from causing undesirable electrical influence on other elements (for example, a touch function layer) when the first reflection assistance element 91 is floated. In other implementation modes, the first reflection assistance element 91 may further be electrically connected to a positive power voltage supply line.

Exemplarily, referring to FIG. 9, the first reflection assistance element 91 extends from the display region 101 to the non-display region 102, and is electrically connected to the reference voltage supply signal line 93 disposed in the non-display region 102. The display panel further includes an auxiliary connection line 94, wherein the first reflection assistance element 91 is electrically connected to the auxiliary connection line 94 through a via hole, and the auxiliary connection line 94 is electrically connected to the reference voltage supply signal line 93 through a via hole.

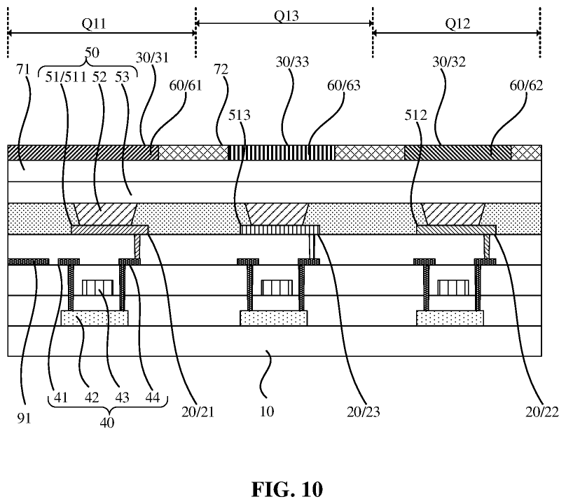

FIG. 10 is a sectional view of a display panel according to another embodiment of the present disclosure. Referring to FIG. 10, the display panel further includes a plurality of pixel drive circuits disposed between the plurality of reflective electrodes 51 and the substrate 10. The first reflection assistance element 91 and any one metal layer in one of the plurality of pixel drive circuits are disposed in a same layer and made of a same material. In the present embodiment of the disclosure, the first reflection assistance element 91 and any one metal layer in the pixel drive circuit are disposed in the same layer and made of the same material, and the first reflection assistance element 91 and the metal layer in the pixel drive circuit can be formed in a same process, thereby simplifying a manufacturing process.

Optionally, referring to FIG. 10, each of the plurality of pixel drive circuits includes the thin film transistor 40, wherein the thin film transistor 40 includes the gate 43, the source 41, the drain 44, and the semiconductor layer 42, and the first reflection assistance element 91, the source 41, and the drain 44 are disposed in a same layer and made of a same material. In the present embodiment of the disclosure, the first reflection assistance element 91, the source 41, and the drain 44 are disposed in the same layer and made of the same material, a vertical distance from a film containing the first reflective electrode 511 to the layer of the source 41 and the drain 44 is relatively small, and a metal material used by the source 41 and the drain 44 has a higher reflectance. Therefore, a difference in reflectance between the first reflection assistance element 91 and the first reflective electrode 511 in the ambient environment is reduced, thereby facilitating a design objective. In other implementation modes, the first reflection assistance element 91 and the gate 43 may further be disposed in a same layer and made of a same material. It is to be noted that the pixel drive circuit may further include a storage capacitor (not shown in FIG. 10), wherein the storage capacitor may include a first polar plate and a second polar plate, the first polar plate and the gate 43 are disposed in a same layer and made of a same material, the second polar plate is disposed between a film where the gate 43 is located and a film where the source 41 is located, and the first reflection assistance element 91 and the second polar plate of the storage capacitor may further be disposed in a same layer and made of a same material.

Optionally, referring to FIGS. 5-8, the first color filter component 31 includes the first color filter 61. In the direction perpendicular to the substrate 10, the first color filter 61 covers at least a portion of the first reflection assistance element 91. That is to say, a vertical projection of the first color filter 61 on the substrate 10 overlaps with a vertical projection of the first reflection assistance element 91 on the substrate 10. In the present embodiment of the disclosure, the first color filter 61 covers the first reflective electrode 511 and at least the portion of the first reflection assistance element 91.

Exemplarily, referring to FIG. 5 and FIG. 6, in the direction perpendicular to the substrate 10, the first color filter 61 covers all of the first reflection assistance element 91. The first color filter 61 is disposed in the first color region Q11 and the second color region Q12.

Exemplarily, referring to FIG. 7 and FIG. 8, in the direction perpendicular to the substrate 10, the first color filter 61 covers the portion of the first reflection assistance element 91. The first color filter 61 is disposed in the first color region Q11 and the second color region Q12. The first reflection assistance element 91 may be a portion of a reflective metal strip disposed in the first color region Q11. In some implementation modes, the first reflection assistance element 91 may further be a portion of the reflective metal strip disposed in a third color region Q13. The reflective metal strip is at least disposed in the first color region Q11 and the second color region Q12. Each reflective metal strip may, for example, be arranged corresponding to one row of pixel regions Q1.

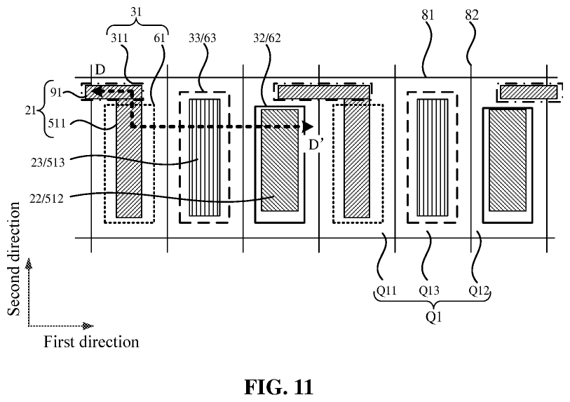

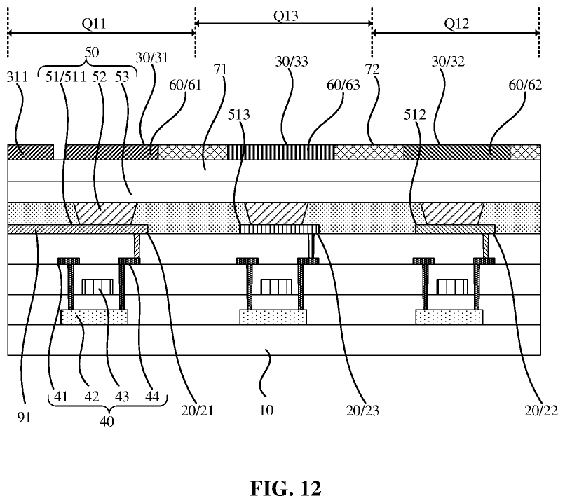

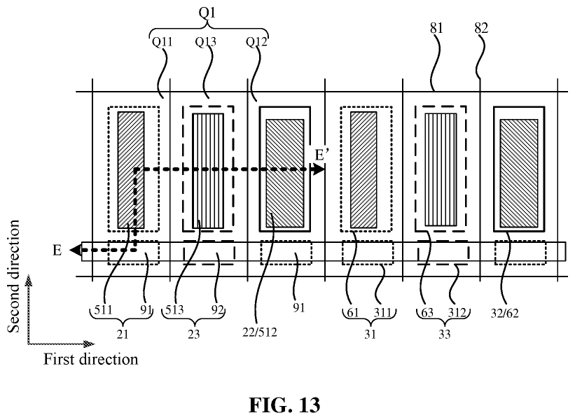

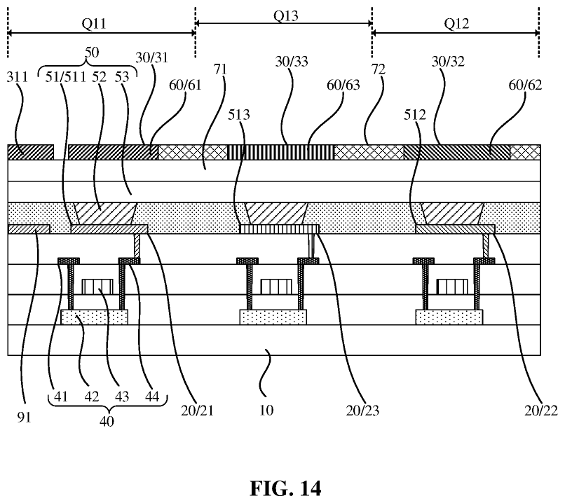

FIG. 11 is a top view of a display panel according to another embodiment of the present disclosure. FIG. 12 is a sectional view of FIG. 11 along a line DD′. FIG. 13 is a top view of a display panel according to another embodiment of the present disclosure. FIG. 14 is a sectional view of FIG. 13 along a line EE′. Referring to FIGS. 11-14, two pixels are shown in FIG. 11 and FIG. 13, the first color filter component 31 includes the first color filter 61 and a first auxiliary color filter 311, where the first color filter 61 is disposed in the first color region Q11, and at least a portion of the first auxiliary color filter 311 is disposed in the first color region Q11. In the direction perpendicular to the substrate 10, the first auxiliary color filter 311 does not overlap with the first color filter 61 and overlaps with the first reflection assistance element 91. In the present embodiment of the disclosure, the first color filter 61 and the first auxiliary color filter 311 together constitute the first color filter component 31 such that a design of the first color filter component 31 is not limited to the first color filter 61. The light in the ambient environment passes through the first color filter component 31 and passes through the first color filter component 31 again after being reflected by the first reflective component 21, and the light in the ambient environment passes through the first auxiliary color filter 311 and passes through the first auxiliary color filter 311 again after being reflected by the first reflection assistance element 91. Therefore, the light that passes through the first color filter component 31 can be reflected by the first reflective component 21 and be seen by human eyes, and the light that passes through the first auxiliary color filter 311 can be reflected by the first reflection assistance element 91 and be seen by human eyes. Therefore, the vertical overlapping area of the first color filter component 31 and the first reflective component 21 is the effective reflective area, and a vertical overlapping area of the first auxiliary color filter 311 and the first reflection assistance element 91 is an effective reflective area.

Exemplarily, referring to FIGS. 11-14, the first color filter 61 and the first auxiliary color filter 311 are disposed in a same layer and made of a same material, and the first color filter 61 and the first auxiliary color filter 311 are formed at the same time in a same process, thereby simplifying a manufacturing process. In other implementation modes, the first color filter 61 and the first auxiliary color filter 311 may further be disposed in different layers which are not limited to the present disclosure.

Optionally, referring to FIGS. 1-14, the reflective component 20 includes the reflective electrode 51, and the color filter component 30 includes the color filter 60. In the direction perpendicular to the substrate 10, the color filter 60 completely covers the reflective electrode 51 in the same pixel region Q1. In the direction perpendicular to the substrate 10, an area of the color filter 60 is greater than an area of the reflective electrode 51 in the same pixel region Q1. An advantage of this configuration is that, in a display state, light which is emitted by the light emitting unit 50 and has a large viewing angle can also be emitted outside the display panel, thereby increasing luminance. In a dark state, the light in the ambient environment reflected by the reflective electrode 51 can pass through the color filter 60 in an inclined state, thereby further reducing influence of the color filter 60 on the color separation phenomenon from the lateral view.

Optionally, referring to FIGS. 1-14, a light transmittance of the first color filter component 31 is equal to a light transmittance of the second color filter component 32. In the present embodiment of the disclosure, in the same pixel, the vertical overlapping area of the first color filter component 31 and the first reflective component 21 is equal to the vertical overlapping area of the second color filter component 32 and the second reflective component 22, and the light transmittance of the first color filter component 31 is equal to the light transmittance of the second color filter component 32, such that the light of the first color reflected through the first color filter component 31 and the light of the second color reflected through the second color filter component 32 have exactly the same light intensity. Therefore, the color separation phenomenon will not occur from the lateral view.

Exemplarily, referring to FIGS. 1-14, in the direction perpendicular to the substrate 10, a light transmittance of a material of the first color filter component 31 is greater than a light transmittance of a material of the second color filter component 32, and a thickness of the first color filter component 31 is configured to be greater than a thickness of the second color filter component 32, such that the light transmittance of the first color filter component 31 is equal to the light transmittance of the second color filter component 32.

Exemplarily, referring to FIG. 2, the first reflective component 21 includes the first reflective electrode 511, the first color filter component 31 includes the first color filter 61, and the first color filter 61 covers the first reflective electrode 511. The second reflective component 22 includes the second reflective electrode 512, the second color filter component 32 includes the second color filter 62, and the second color filter 62 covers the second reflective electrode 512. In the direction perpendicular to the substrate 10, the area of the first reflective electrode 511 is S1, the area of the second reflective electrode 512 is S2, and S1 is equal to S2. A light transmittance of the first color filter 61 is T1, a light transmittance of the second color filter 62 is T2, and T1 is equal to T2. Luminance of the light in the ambient environment after being reflected by the first reflective electrode 511 and passing through the first color filter 61 is T1^{1/cos θ} [symbol] 1, where θ is an incident angle of light in the ambient environment. Luminance of the light in the ambient environment after being reflected by the second reflective electrode 512 and passing through the second color filter 62 is T2^{1/cos θ} [symbol] 2. Since S1=S2, and T1=T2, it follows that T1^{1/cos θ} [symbol] 1=T2^{1/cos θ} [symbol] 2. That is to say, at any viewing angle, when the display panel is in the dark state, the light of the first color and the light of the second color among the reflected light in the ambient environment have the same luminance, such that the color separation phenomenon will not occur from the lateral view.

It is to be noted that the first color region Q11 and the second color region Q12 are used as examples for illustration in all the above-mentioned embodiments, and when the display panel includes pixel regions Q1 with at least three different light emitting colors, pixel regions Q1 of two different light emitting colors among the pixel regions Q1 can satisfy the description in the above-mentioned embodiments. Another embodiment of the present disclosure is further described by using pixel regions Q1 with three different light emitting colors as examples.

Optionally, referring to FIG. 1, FIG. 2, and FIG. 3, the plurality of pixel regions Q1 further includes the third color region Q13. An emission wavelength of the third color region Q13 is greater than the emission wavelength of the second color region Q12 and is not equal to the emission wavelength of the first color region Q11. The plurality of reflective components 20 further includes a third reflective component 23, where at least a portion of the third reflective component 23 is disposed in the third color region Q13. The plurality of color filter components 30 further includes a third color filter component 33, where at least a portion of the third color filter component 33 is disposed in the third color region Q13 and the third color filter component 33 is transmissive for light of a third color. In the direction perpendicular to the substrate 10, in the same pixel (one pixel is shown in FIG. 2), the overlapping area of the first color filter component 31 and the first reflective component 21 is equal to an overlapping area of the third color filter component 33 and the third reflective component 23.

Exemplarily, referring to FIG. 1 to FIG. 3, the emission wavelength of the third color region Q13 may be less than the emission wavelength of the first color region Q11. The first color region Q11 emits the red light, the second color region Q12 emits the blue light, and the third color region Q13 emits the green light.

In the present embodiment of the disclosure, in the same pixel (one pixel is shown in FIG. 2), the vertical overlapping area of the first color filter component 31 and the first reflective component 21 is equal to the vertical overlapping area of the second color filter component 32 and the second reflective component 22, and the vertical overlapping area of the first color filter component 31 and the first reflective component 21 is equal to a vertical overlapping area of the third color filter component 33 and the third reflective component 23. In this way, the effective reflective area corresponding to the first color filter component 31, the effective reflective area corresponding to the second color filter component 32, and an effective reflective area corresponding to the third color filter component 33 are the same, such that the light of the first color reflected through the first color filter component 31 and the light of the second color reflected through the second color filter component 32 have similar light intensities or even the same light intensity, and the light of the first color reflected through the first color filter component 31 and the light of the third color reflected through the third color filter component 33 have similar light intensities or even the same light intensity, thereby solving the problem of color separation from the lateral view.

Optionally, referring to FIG. 1, FIG. 2, and FIG. 3, the reflective component 20 includes the reflective electrode 51, where the reflective electrode 51 refers to the electrode having the function of reflecting light. The color filter component 30 includes the color filter 60. In the direction perpendicular to the substrate 10, the color filter 60 completely covers the reflective electrode 51 in the same pixel region Q1. The plurality of reflective electrodes 51 includes the first reflective electrode 511 disposed in the first color region Q11, the second reflective electrode 512 disposed in the second color region Q12, and a third reflective electrode 513 disposed in the third color region Q13. In the direction perpendicular to the substrate 10, the area of the first reflective electrode 511 is equal to the area of the second reflective electrode 512, and is further equal to an area of the third reflective electrode 513. In the embodiment of the present disclosure, the reflective electrode 51 serves as the reflective component 20, the color filter 60 serves as the color filter component 30, and the color filter 60 completely covers the reflective electrode 51 in the same pixel region Q1. Therefore, as long as vertical projections of the first reflective electrode 511, the second reflective electrode 512 and the third reflective electrode 513 on the substrate 10 have a same area, it can be ensured that in the same pixel (one pixel is shown in FIG. 2), the vertical overlapping area of the first color filter component 31 and the first reflective component 21 is equal to the vertical overlapping area of the second color filter component 32 and the second reflective component 22, and is further equal to the vertical overlapping area of the third color filter component 33 and the third reflective component 23, thereby simplifying the design process.

Optionally, referring to FIG. 13 and FIG. 14, the reflective component 20 includes the reflective electrode 51, and the color filter component 30 includes the color filter 60. In the direction perpendicular to the substrate 10, the color filter 60 completely covers the reflective electrode 51 in the same pixel region Q1. The first reflective component 21 includes the first reflective electrode 511 and the first reflection assistance element 91, where the first reflective electrode 511 is disposed in the first color region Q11. The second reflective component 22 includes the second reflective electrode 512, where the second reflective electrode 512 is disposed in the second color region Q12. The third reflective component 23 includes the third reflective electrode 513 and a second reflection assistance element 92, where the third reflective electrode 513 is disposed in the third color region Q13. In the direction perpendicular to the substrate 10, the first color filter component 31 covers at least the portion of the first reflection assistance element 91, and the third color filter component 33 covers at least a portion of the second reflection assistance element 92. In the direction perpendicular to the substrate 10, in the same pixel (two pixels are shown in FIG. 13), the overlapping area of the first color filter component 31 and the first reflection assistance element 91 constitutes the first area, and an overlapping area of the third color filter component 33 and the second reflection assistance element 92 constitutes a second area. The sum of the first area and an area of the first reflective electrode 511 is equal to a total area of the second reflective electrode 512, and a sum of the second area and an area of the third reflective electrode 513 is equal to the total area of the second reflective electrode 512. In the present embodiment of the disclosure, the first reflective electrode 511 and the first reflection assistance element 91 together constitute the first reflective component 21 such that the design of the first reflective component 21 is not limited to the first reflective electrode 511. The third reflective electrode 513 and the second reflection assistance element 92 together constitute the third reflective component 23 such that a design of the third reflective component 23 is not limited to the third reflective electrode 513.

Exemplarily, referring to FIG. 13 and FIG. 14, the first reflection assistance element 91 may be the portion of the reflective metal strip disposed in the first color region Q11, and, in some implementation modes, the first reflection assistance element 91 may further be a portion of the reflective metal strip disposed in the third color region Q13. The second reflection assistance element 92 may be a portion of the reflective metal strip disposed in the second color region Q12, and the reflective metal strip is at least disposed in the first color region Q11, the second color region Q12, and the third color region Q13. The first reflection assistance element 91 and the second reflection assistance element 92 are different positions of a same reflective metal strip. Each reflective metal strip may be, for example, disposed corresponding to one row of pixel regions Q1. In other implementation modes, the first reflection assistance element 91 and the second reflection assistance element 92 may further be a plurality of discrete reflective metal blocks.

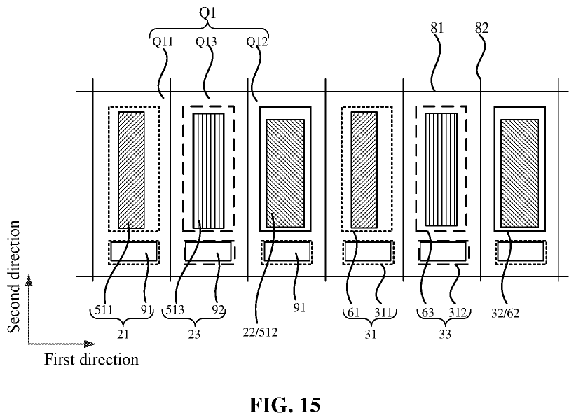

FIG. 15 is a top view of a display panel according to another embodiment of the present disclosure. Referring to FIG. 15, two pixels are shown in FIG. 15, and the first reflective component 21 includes the first reflective electrode 511 and the first reflection assistance element 91, where the first reflective electrode 511 is disposed in the first color region Q11. The second reflective component 22 includes the second reflective electrode 512, where the second reflective electrode 512 is disposed in the second color region Q12. The third reflective component 23 includes the third reflective electrode 513 and the second reflection assistance element 92, where the third reflective electrode 513 is disposed in the third color region Q13. In the direction perpendicular to the substrate 10, the first color filter 61 covers the first reflective electrode 511, and the first auxiliary color filter 311 covers the first reflection assistance element 91. In the direction perpendicular to the substrate 10, a third color filter 63 covers the third reflective electrode 513, and a second auxiliary color filter 312 covers the second reflection assistance element 92. The first reflection assistance element 91 and the second reflection assistance element 92 constitute the plurality of discrete reflective metal blocks.

Exemplarily, referring to FIG. 13 and FIG. 15, the first auxiliary color filter 311 and the first reflection assistance element 91 are disposed in the first color region Q11 and the second color region Q12. The second auxiliary color filter 312 and the second reflection assistance element 92 are disposed in the third color region Q13. In some implementation modes, the first auxiliary color filter 311 and the first reflection assistance element 91 may be only disposed in the first color region Q11, and the second auxiliary color filter 312 and the second reflection assistance element 92 may be disposed in the third color region Q13 and the second color region Q12. In another implementation mode, the first auxiliary color filter 311 and the first reflection assistance element 91 may be only disposed in the first color region Q11, and the second auxiliary color filter 312 and the second reflection assistance element 92 may be only disposed in the third color region Q13.

Optionally, referring to FIGS. 1-15, the light transmittance of the first color filter component 31 is equal to the light transmittance of the second color filter component 32, and is further equal to a light transmittance of the third color filter component 33. In the present embodiment of the disclosure, in the same pixel, the vertical overlapping area of the first color filter component 31 and the first reflective component 21 is equal to the vertical overlapping area of the second color filter component 32 and the second reflective component 22, and the light transmittance of the first color filter component 31 is equal to the light transmittance of the second color filter component 32, such that the light of the first color reflected through the first color filter component 31 and the light of the second color reflected through the second color filter component 32 have completely the same light intensity. In the same pixel, the vertical overlapping area of the first color filter component 31 and the first reflective component 21 is equal to the vertical overlapping area of the third color filter component 33 and the third reflective component 23, and the light transmittance of the first color filter component 31 is equal to the light transmittance of the third color filter component 33, such that the light of the first color reflected through the first color filter component 31 and the light of the third color reflected through the third color filter component 33 have exactly the same light intensity. Therefore, the color separation phenomenon will not occur from the lateral view.

Exemplarily, referring to FIGS. 1-15, in the direction perpendicular to the substrate 10, the light transmittance of the material of the first color filter component 31 is greater than the light transmittance of the material of the second color filter component 32, and the thickness of the first color filter component 31 is configured to be greater than the thickness of the second color filter component 32, such that the light transmittance of the first color filter component 31 is equal to the light transmittance of the second color filter component 32. In the direction perpendicular to the substrate 10, a light transmittance of a material of the third color filter component 33 is greater than the light transmittance of the material of the second color filter component 32, and a thickness of the third color filter component 33 is configured to be greater than the thickness of the second color filter component 32, such that the light transmittance of the third color filter component 33 is equal to the light transmittance of the second color filter component 32.

Furthermore, the emission wavelength of the third color region Q13 may be less than the emission wavelength of the first color region Q11. In the direction perpendicular to the substrate 10, the light transmittance of the material of the first color filter component 31 is greater than the light transmittance of the material of the third color filter component 33, and the thickness of the first color filter component 31 is configured to be greater than the thickness of the third color filter component 33, such that the light transmittance of the third color filter component 33 is equal to the light transmittance of the first color filter component 31.

Exemplarily, referring to FIG. 2, the first reflective component 21 includes the first reflective electrode 511, the first color filter component 31 includes the first color filter 61, and the first color filter 61 covers the first reflective electrode 511. The second reflective component 22 includes the second reflective electrode 512, the second color filter component 32 includes the second color filter 62, and the second color filter 62 covers the second reflective electrode 512. The third reflective component 23 includes the third reflective electrode 513, the third color filter component 33 includes the third color filter 63, and the third color filter 63 covers the third reflective electrode 513. The area of the first reflective electrode 511 is S1, the area of the second reflective electrode 512 is S2, the area of the third reflective electrode is S3, and S1, S2, and S3 are equal. The light transmittance of the first color filter 61 is T1, the light transmittance of the second color filter 62 is T2, a light transmittance of the third color filter 63 is T3, and T1, T2, and T3 are equal. The luminance of the light in the ambient environment after being reflected by the first reflective electrode 511 and passing through the first color filter 61 is T1^{1/cos θ} [symbol] 1, where θ is an incident angle of light in the ambient environment. The luminance of the light in the ambient environment after being reflected by the second reflective electrode 512 and passing through the second color filter 62 is T2^{1/cos θ} [symbol] 2. The luminance of the light in the ambient environment after being reflected by the third reflective electrode 513 and passing through the third color filter 63 is T3^{1/cos θ} [symbol] 3. Since S1=S2=S3, and T1=T2=T3, it follows that T1^{1/cos θ} [symbol] 1=T2^{1/cos θ} [symbol] 2=T3^{1/cos θ} [symbol] 3. That is to say, at any viewing angle, when the display panel is in the dark state, the light of the first color, the light of the second color, and the light of the third color among the reflected light in the ambient environment have the same luminance, such that the color separation phenomenon will not occur from the lateral view.

Exemplarily, as shown in FIG. 1 and FIG. 2, in the same pixel, the first color filter component 31, the second color filter component 32, and the third color filter component 33 are arranged in sequence along the first direction. In other implementation modes, the display panel may also have other pixel arrangement modes, and the pixel arrangement modes are not limited to the present disclosure.

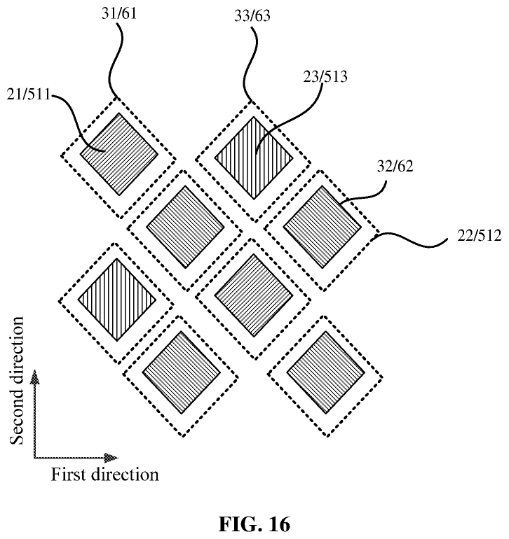

FIG. 16 is a top view of a display panel according to another embodiment of the present disclosure. Referring to FIG. 16, in the same pixel, two first color filter components 31, four second color filter components 32, and two third color filter components 33 are included. In the direction perpendicular to the substrate 10, in the same pixel, the overlapping area of the first color filter components 31 and the first reflective components 21 is equal to the overlapping area of the second color filter components 32 and the second reflective components 22. The overlapping area of the first color filter components 31 and the first reflective components 21 is equal to the overlapping area of the third color filter components 33 and the third reflective components 23.

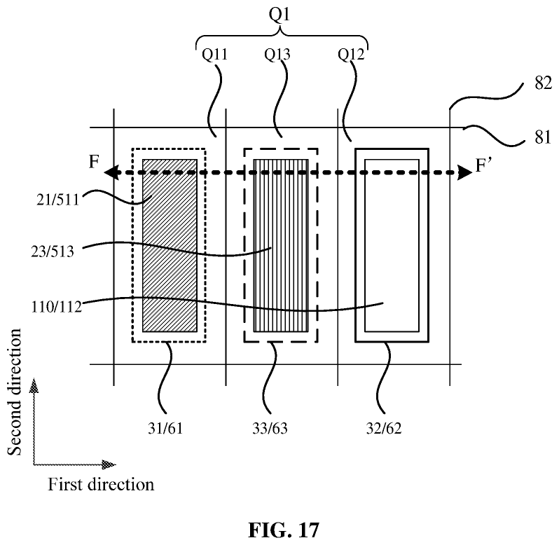

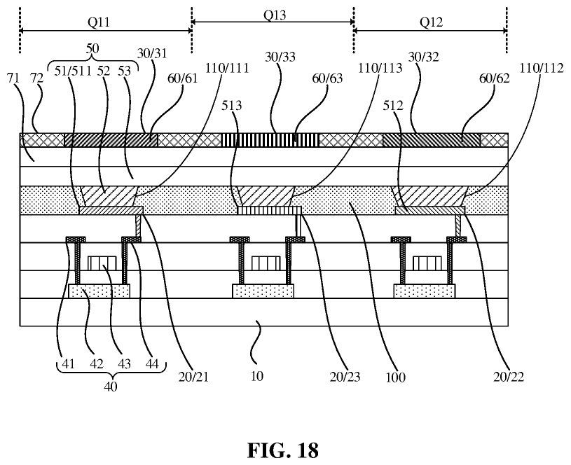

FIG. 17 is a top view of a display panel according to another embodiment of the present disclosure. FIG. 18 is a sectional view of FIG. 17 along a line FF. Referring to FIG. 17 and FIG. 18, the display panel includes the display region 101, wherein the display region 101 includes the plurality of pixels, each of the plurality of pixels includes the plurality of pixel regions Q1 (exemplarily, in FIG. 17, one pixel includes three pixel regions Q1), and each of the plurality of pixel regions Q1 includes the first color region Q11 and the second color region Q12, wherein the emission wavelength of the first color region Q11 is greater than the emission wavelength of the second color region Q12. The first color region Q11 emits the light of the first color, and the second color region Q12 emits the light of the second color. The display panel includes the substrate 10, the plurality of reflective components 20, a pixel definition layer 100 and the plurality of color filter components 30. The plurality of reflective components 20 is disposed on the side of the substrate 10 and includes the first reflective component 21 and the second reflective component 22, where at least the portion of the first reflective component 21 is disposed in the first color region Q11, and the second reflective component 22 is disposed in the second color region Q12. Each of the plurality of reflective components 20 includes the reflective electrode 51. The pixel definition layer 100 is disposed on the side of the plurality of reflective components 20 facing away from the substrate 10 and configured with a plurality of openings 110, and, in the direction perpendicular to the substrate 10, the reflective electrode 51 completely covers a bottom of an opening 110 on a side of the opening 110 facing towards the substrate 10. The plurality of openings 110 includes a first opening 111 disposed in the first color region Q11 and a second opening 112 disposed in the second color region Q12, wherein the second opening 112 has a bottom side facing towards substrate 10. A transmittance of the pixel definition layer 100 for the light of the first color is greater than a transmittance of the pixel definition layer 100 for the light of the second color. The plurality of color filter components 30 is disposed on a side of the pixel definition layer 100 facing away from the substrate 10, wherein the plurality of color filter components 30 includes the first color filter component 31 and the second color filter component 32, at least the portion of the first color filter component 31 is disposed in the first color region Q11 and the first color filter component 31 is transmissive for the light of the first color, and the second color filter component 32 is disposed in the second color region Q12 and transmissive for the light of the second color. In the direction perpendicular to the substrate 10, in the same pixel (one pixel is shown in FIG. 17), the overlapping area of the first color filter component 31 and the first reflective component 21 is equal to a sum of areas of the bottom sides of the second opening 112

It is to be noted that in the top view of the display panel according to each embodiment of the present disclosure, in order to clearly illustrate the opening 110, the reflective electrode overlapping with the opening 110 is omitted. Furthermore, the opening 110 in the top view of the display panel according to each embodiment illustrates the bottom of the opening 110 on the side of the opening 110 facing towards the substrate 10.

In the display panel provided by the present embodiment of the disclosure, the transmittance of the pixel definition layer 100 for the light of the first color is greater than the transmittance of the pixel definition layer 100 for the light of the second color, and the pixel definition layer 100 is transmissive for the light of the first color and absorbs the light of the second color. Therefore, the pixel definition layer 100 in the first color region Q11 has little influence on the light of the first color, and the light of the first color which passes through the first color filter component 31 will not be absorbed and can be reflected outside the display panel by the first reflective component 21. The pixel definition layer 100 in the second color region Q12 has larger influence on the light of the second color. In the second color region Q12, little light passes through the pixel definition layer 100 and is incident to the second reflective component 22, and the light of the second color which passes through the second color filter component 32 will be absorbed and cannot be reflected outside the display panel. In the present embodiment of the disclosure, in the same pixel, the vertical overlapping area of the first color filter component 31 and the first reflective component 21 is equal to the sum of the areas of the bottom sides of the second opening 112, such that the effective reflective area corresponding to the first color filter component 31 is equal to the effective reflective area corresponding to the second color filter component 32, and the light of the first color reflected through the first color filter component 31 and the light of the second color reflected through the second color filter component 32 have similar light intensities or even the same light intensity, thereby solving the problem of color separation from the lateral view.

Optionally, referring to FIG. 17 and FIG. 18, the plurality of pixel regions Q1 further includes the third color region Q13. The third color region Q13 emits the light of the third color. The emission wavelength of the third color region Q13 is greater than the emission wavelength of the second color region Q12 and is not equal to the emission wavelength of the first color region Q11. The plurality of reflective components 20 further includes the third reflective component 23, where the third reflective component 23 is disposed in the third color region Q13. The plurality of openings 110 further includes a third opening 113 disposed in the third color region Q13, and a transmittance of the pixel definition layer 100 for the light of the third color is greater than the transmittance of the pixel definition layer 100 for the light of the second color. The plurality of color filter components 30 further includes the third color filter component 33, where the third color filter component 33 is disposed in the third color region Q13 and transmissive for the light of the third color. In the direction perpendicular to the substrate 10, in the same pixel, the overlapping area of the third color filter component 33 and the third reflective component 23 is equal to the sum of the areas of the bottom sides of the second openings 112.

Exemplarily, referring to FIG. 17 and FIG. 18, the emission wavelength of the third color region Q13 may be, for example, less than the emission wavelength of the first color region Q11. The first color region Q11 emits the red light, the second color region Q12 emits the blue light, and the third color region Q13 emits the green light.

In the present embodiment of the disclosure, the pixel definition layer 100 is transmissive for the light of the first color and the light of the third color and absorbs the light of the second color. In the same pixel, the vertical overlapping area of the first color filter component 31 and the first reflective component 21 is equal to the sum of the areas of the bottom sides of the second openings 112, and the vertical overlapping area of the third color filter component 33 and the third reflective component 23 is equal to the sum of the areas of the bottom sides of the second openings 112, such that the effective reflective area corresponding to the first color filter component 31, the effective reflective area corresponding to the second color filter component 32, and the effective reflective area corresponding to the third color filter component 33 are the same, and the light of the first color reflected through the first color filter component 31, the light of the second color reflected through the second color filter component 32, and the light of the third color reflected through the third color filter component 33 have similar light intensities or even the same light intensity, thereby solving the problem of color separation from the lateral view.

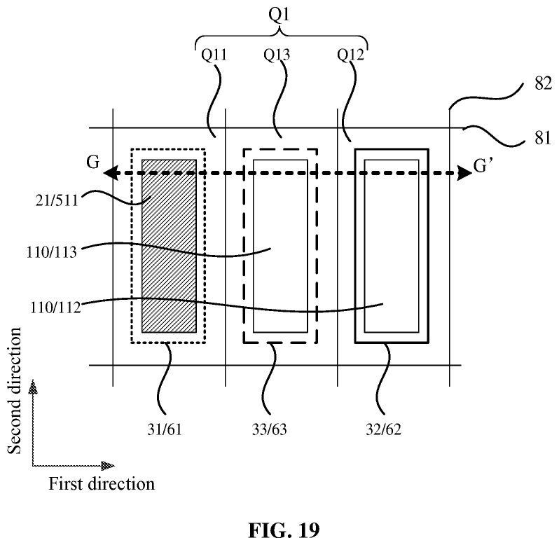

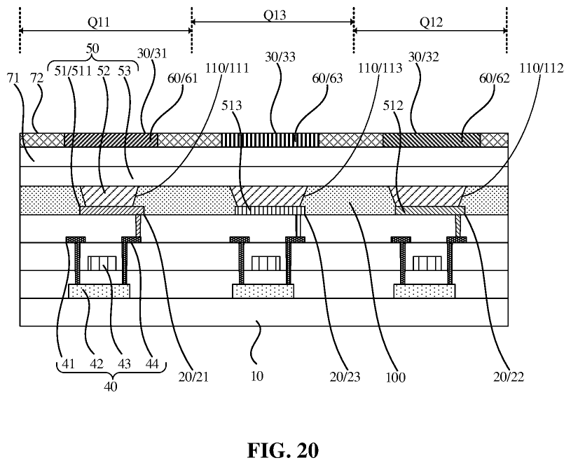

FIG. 19 is a top view of another display panel according to an embodiment of the present disclosure. FIG. 20 is a sectional view of FIG. 19 along a line GG′. Referring to FIG. 19 and FIG. 20, one pixel is shown in FIG. 19, and the plurality of pixel regions Q1 further includes the third color region Q13. The third color region Q13 emits the light of the third color. The emission wavelength of the third color region Q13 is greater than the emission wavelength of the second color region Q12 and is not equal to the emission wavelength of the first color region Q11. The plurality of openings 110 further includes the third opening 113 disposed in the third color region Q13, wherein the third opening 113 has a bottom side facing towards substrate 10, and the transmittance of the pixel definition layer 100 for the light of the first color is greater than the transmittance of the pixel definition layer 100 for the light of the third color. The plurality of color filter components 30 further includes the third color filter component 33, where the third color filter component 33 is disposed in the third color region Q13 and transmissive for the light of the third color. In the direction perpendicular to the substrate 10, in the same pixel, the sum of the areas of the bottom sides of all the second openings 112 is equal to a sum of areas of bottom sides of all third openings 113.

In the present embodiment of the disclosure, the pixel definition layer 100 is transmissive for the light of the first color and absorbs the light of the second color and the light of the third color. In the same pixel (one pixel is shown in FIG. 19), the vertical overlapping area of the first color filter component 31 and the first reflective component 21 is equal to the sum of the areas of the bottom sides of all the second openings 112, and the sum of the areas of the bottom sides of all the second openings 112 is equal to the sum of the areas of the bottom sides of all the third openings 113, such that the effective reflective area corresponding to the first color filter component 31, the effective reflective area corresponding to the second color filter component 32, and the effective reflective area corresponding to the third color filter component 33 are the same, and the light of the first color reflected through the first color filter component 31, the light of the second color reflected through the second color filter component 32, and the light of the third color reflected through the third color filter component 33 have similar light intensities or even the same light intensity, thereby solving the problem of color separation from the lateral view.

Exemplarily, referring to FIG. 19 and FIG. 20, the light transmittance of the first color filter component 31 is equal to the light transmittance of the second color filter component 32, and is further equal to the light transmittance of the third color filter component 33. In the present embodiment of the disclosure, in the same pixel, the vertical overlapping area of the first color filter component 31 and the first reflective component 21 is equal to the sum of the areas of the bottom sides of the second openings 112, and the light transmittance of the first color filter component 31 is equal to the light transmittance of the second color filter component 32, such that the light of the first color reflected through the first color filter component 31 and the light of the second color reflected through the second color filter component 32 have exactly the same light intensity. In the same pixel, the vertical overlapping area of the first color filter component 31 and the first reflective component 21 is equal to the sum of the areas of the bottom sides of the third openings 113, and the light transmittance of the first color filter component 31 is equal to the light transmittance of the third color filter component 33, such that the light of the first color reflected through the first color filter component 31 and the light of the third color reflected through the third color filter component 33 have exactly the same light intensity. Therefore, the color separation phenomenon will not occur from the lateral view.

Optionally, referring to FIG. 17 to FIG. 20, the transmittance of the pixel definition layer 100 for the light of the first color is greater than 40%, and the transmittance of the pixel definition layer 100 for the light of the second color is less than 10%. In practical display panel products, a transmittance of any optical film that is light transmissive is effectively less than 100%, and a transmittance of any optical film that absorbs light is effectively greater than 0%. When the transmittance of the pixel definition layer 100 for the light of the first color is greater than 40%, it can be considered that the pixel definition layer 100 is transmissive for the light of the first color. It can be understood that the transmittance of the pixel definition layer 100 for the light of the first color should be as great as possible. When the transmittance of the pixel definition layer 100 for the light of the second color is less than 10%, it can be considered that the pixel definition layer 100 absorbs the light of the second color. It can be understood that the transmittance of the pixel definition layer 100 for the light of the second color should be as small as possible.

Exemplarily, the transmittance of the pixel definition layer 100 for the light of the first color is greater than the transmittance of the pixel definition layer 100 for the light of the third color, the pixel definition layer 100 absorbs the light of the third color, and the transmittance of the pixel definition layer 100 for the light of the third color may be less than 10%. Exemplarily, the transmittance of the pixel definition layer 100 for the light of the third color is greater than the transmittance of the pixel definition layer 100 for the light of the second color, the pixel definition layer 100 is transmissive for the light of the third color, and the transmittance of the pixel definition layer 100 for the light of the third color may be greater than 40%.

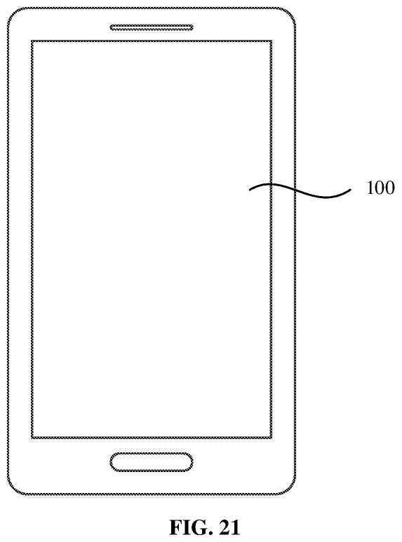

Another embodiment of the present disclosure further provides a display device. FIG. 21 is a structural diagram of a display device according to an embodiment of the present disclosure. Referring to FIG. 21, the display device includes any one of the display panels 100 provided by the embodiments of the present disclosure. The display device may specifically be a mobile phone, a tablet computer, a smart wearable apparatus, and so on.

It is to be noted that the above are merely preferred embodiments of the present disclosure and the technical principles used therein. It is further understood by those skilled in the art that the present disclosure is not limited to the specific embodiments described herein. Those skilled in the art can make various apparent modifications, adaptations, combinations, and substitutions without departing from the scope of the present disclosure. Therefore, while the present disclosure has been described in detail through the above-mentioned embodiments, the present disclosure is not limited to the above-mentioned embodiments and may further include other, equivalent embodiments without departing from the concept of the present disclosure.

What is claimed is:

1. A display panel, comprising:
a display region, wherein the display region comprises a plurality of pixels, each of the plurality of pixels comprises a plurality of pixel regions, and the plurality of pixel regions comprises a first color region and a second color region, wherein an emission wavelength of the first color region is greater than an emission wavelength of the second color region;
a substrate;
a plurality of reflective components disposed on a side of the substrate, wherein the plurality of reflective components comprises a first reflective component and a second reflective component, at least a portion of the first reflective component is disposed in the first color region, and the second reflective component is disposed in the second color region; and
a plurality of color filter components disposed on a side of the plurality of reflective components facing away from the substrate, wherein the plurality of color filter components comprises a first color filter component and a second color filter component, at least a portion of the first color filter component is disposed in the first color region and the first color filter component is transmissive for light of a first color, and the second color filter component is disposed in the second color region and transmissive for light of a second color; wherein
in a direction perpendicular to the substrate, in a same pixel among the plurality of pixels, an overlapping area of the first color filter component and the first reflective component is equal to an overlapping area of the second color filter components and the second reflective component.

2. The display panel of claim 1, wherein
each of the plurality of reflective components comprises a reflective electrode, each of the plurality of color filter components comprises a color filter, wherein in the direction perpendicular to the substrate, the color filter completely covers the reflective electrode in a same pixel region among the plurality of pixel regions; and
a plurality of reflective electrodes of the plurality of reflective components comprises a first reflective electrode disposed in the first color region and a second reflective electrode disposed in the second color region, wherein in the direction perpendicular to the substrate, an area of the first reflective electrode is equal to an area of the second reflective electrode.

3. The display panel of claim 2, wherein the plurality of pixel regions is arranged in a matrix along a first direction and a second direction;
along the first direction, a width of the first reflective electrode is equal to a width of the second reflective electrode; and
along the second direction, a length of the first reflective electrode is equal to a length of the second reflective electrode.

4. The display panel of claim 2, wherein the plurality of pixel regions is arranged in a matrix along a first direction and a second direction;
along the first direction, a width of the first reflective electrode is less than a width of the second reflective electrode; and
along the second direction, a length of the first reflective electrode is greater than a length of the second reflective electrode.

5. The display panel of claim 1, wherein
each of the plurality of reflective components comprises a reflective electrode and each of the plurality of color filter components comprises a color filter, wherein in the direction perpendicular to the substrate, the color filter completely covers the reflective electrode in a same pixel region among the plurality of pixel regions;
the first reflective component comprises a first reflective electrode and a first reflection assistance element, wherein the first reflective electrode is disposed in the first color region; and
the second reflective component comprises a second reflective electrode, wherein the second reflective electrode is disposed in the second color region;
in the direction perpendicular to the substrate, the first color filter component covers at least a portion of the first reflection assistance element; and
in the direction perpendicular to the substrate, in the same pixel, an overlapping area of the first color filter component and first reflection assistance element constitutes a first area, and a sum of the first area and an area of the first reflective electrode is equal to a total area of the second reflective electrode.

6. The display panel of claim 5, wherein the first reflection assistance element and the first reflective electrode are disposed in a same layer and made of a same material, the first reflection assistance element is electrically connected to the first reflective electrode, and in the direction perpendicular to the substrate, the first reflection assistance element does not overlap with the second reflective electrode.

7. The display panel of claim 5, wherein the first reflection assistance element is electrically insulated from any one of the plurality of reflective electrodes.

8. The display panel of claim 7, wherein the first reflection assistance element and the first reflective electrode are disposed in a same layer and made of a same material.

9. The display panel of claim 7, further comprising a reference voltage supply signal line and a positive power voltage supply line, wherein the first reflection assistance element is electrically connected to the reference voltage supply signal line or the positive power voltage supply line.

10. The display panel of claim 7, further comprising a plurality of pixel drive circuits disposed between the plurality of reflective electrodes and the substrate; wherein
the first reflection assistance element and any one metal layer in one of the plurality of pixel drive circuits are disposed in a same layer and made of a same material.

11. The display panel of claim 10, wherein each of the plurality of pixel drive circuits comprises a thin film transistor, wherein the thin film transistor comprises a gate, a source, a drain, and a semiconductor layer, and the first reflection assistance element, the source, and the drain are disposed in a same layer and made of a same material.

12. The display panel of claim 5, wherein the first color filter component comprises a first color filter; wherein
in the direction perpendicular to the substrate, the first color filter covers at least the portion of the first reflection assistance element.

13. The display panel of claim 5, wherein the first color filter component comprises a first color filter and a first auxiliary color filter, wherein the first color filter is disposed in the first color region, and at least a portion of the first auxiliary color filter is disposed in the first color region; and
in the direction perpendicular to the substrate, the first auxiliary color filter does not overlap with the first color filter and overlaps with the first reflection assistance element.

14. The display panel of claim 2, wherein in the direction perpendicular to the substrate, an area of the color filter is greater than an area of the reflective electrode in the same pixel region.

15. The display panel of claim 5, wherein in the direction perpendicular to the substrate, an area of the color filter is greater than an area of the reflective electrode in the same pixel region.

16. The display panel of claim 1, wherein the plurality of pixel regions further comprises a third color region, wherein an emission wavelength of the third color region is greater than the emission wavelength of the second color region and is not equal to the emission wavelength of the first color region;
the plurality of reflective components further comprises a third reflective component, wherein at least a portion of the third reflective component is disposed in the third color region;
the plurality of color filter components further comprises a third color filter component, wherein at least a portion of the third color filter component is disposed in the third color region and the third color filter component is transmissive for light of a third color; and
in the direction perpendicular to the substrate, in the same pixel, the overlapping area of the first color filter component and the first reflective component is equal to an overlapping area of the third color filter component and the third reflective component.

17. The display panel of claim 16, wherein each of the plurality of reflective components comprises a reflective electrode, each of the plurality of color filter components comprises a color filter, wherein in the direction perpendicular to the substrate, the color filter completely covers the reflective electrode in a same pixel region among the plurality of pixel regions;
a plurality of reflective electrodes comprises a first reflective electrode disposed in the first color region, a second reflective electrode disposed in the second color region, and a third reflective electrode disposed in the third color region; and
in the direction perpendicular to the substrate, an area of the first reflective electrode is equal to an area of the second reflective electrode and to an area of the third reflective electrode.

18. The display panel of claim 16, wherein
each of the plurality of reflective components comprises a reflective electrode, each of the plurality of color filter components comprises a color filter, wherein in the direction perpendicular to the substrate, the color filter completely covers the reflective electrode in a same pixel region among the plurality of pixel regions;
the first reflective component comprises a first reflective electrode and a first reflection assistance element, wherein the first reflective electrode is disposed in the first color region; the second reflective component comprises a second reflective electrode, wherein the second reflective electrode is disposed in the second color region; and the third reflective component comprises a third reflective electrode and a second reflection assistance element, wherein the third reflective electrode is disposed in the third color region;
in the direction perpendicular to the substrate, the first color filter component covers at least a portion of the first reflection assistance element, and the third color filter component covers at least a portion of the second reflection assistance element;
in the direction perpendicular to the substrate, in the same pixel, an overlapping area of the first color filter component and the first reflection assistance element constitutes a first area, and an overlapping area of the third color filter component and the second reflection assistance element constitutes a second area; and
in the same pixel, a sum of the first area and an area of the first reflective electrode is equal to a total area of the second reflective electrode, and a sum of the second area and an area of the third reflective electrode is equal to the total area of the second reflective electrode.

19. The display panel of claim 16, wherein a light transmittance of the first color filter component is equal to a light transmittance of the second color filter component and is equal to a light transmittance of the third color filter component.

20. A display device, comprising a display panel, wherein the display panel comprises:
a display region, wherein the display region comprises a plurality of pixels, each of the plurality of pixels comprises a plurality of pixel regions, and the plurality of pixel regions comprises a first color region and a second color region, wherein an emission wavelength of the first color region is greater than an emission wavelength of the second color region;
a substrate;
a plurality of reflective components disposed on a side of the substrate, wherein the plurality of reflective components comprises a first reflective component and a second reflective component, at least a portion of the first reflective component is disposed in the first color region, and the second reflective component is disposed in the second color region; and
a plurality of color filter components disposed on a side of the plurality of reflective components facing away from the substrate, wherein the plurality of color filter components comprises a first color filter component and a second color filter component, at least a portion of the first color filter component is disposed in the first color region and the first color filter component is transmissive for light of a first color, and the second color filter component is disposed in the second color region and transmissive for light of a second color; wherein
in a direction perpendicular to the substrate, in a same pixel among the plurality of pixels, an overlapping area of the first color filter component and the first reflective component is equal to an overlapping area of the second color filter component and the second reflective component.
